(19) United States
(12) Patent Application Publication
(10) Pub. No.: US 2025/0253177 A1
(43) Pub. Date: Aug. 7, 2025

(54) SEMICONDUCTOR WAFER TRANSPORT CONTAINER AND METHOD FOR MANUFACTURING SAME

(71) Applicant: Kioxia Corporation, Tokyo (JP)

(72) Inventor: Koji ASAKAWA, Kawasaki Kanagawa (JP)

(73) Assignee: Kioxia Corporation, Tokyo (JP)

(21) Appl. No.: 19/187,335

(22) Filed: Apr. 23, 2025

Related U.S. Application Data
(63) Continuation of application No. PCT/JP2022/041135, filed on Nov. 4, 2022.

(51) Int. Cl. H01L 21/673

(52) U.S. Cl. CPC H01L 21/67366

(57) ABSTRACT

A semiconductor wafer transport container of an embodiment includes a resin container configured to store a semiconductor wafer. The vicinity of a surface of the resin of at least an inner surface of the resin container is impregnated with aluminum oxide having a hydroxyl group. A structure i0n which 1 atomic % or more of the aluminum oxide in terms of the concentration of elemental aluminum is dispersed in the resin is present within at least a range of not less than 50 nm nor more than 10 μm in depth from the inner surface.

### CROSS REFERENCE TO RELATED APPLICATION

This application is based upon and claims the benefit of priority from PCT Patent Application PCT/JP2022/041135, filed on Nov. 4, 2022; the entire contents of which are incorporated herein by reference.

### FIELD

Embodiments of the present invention relate to a semiconductor wafer transport container and a method for manufacturing the same.

### BACKGROUND

In a semiconductor manufacturing process, various chemicals and gases are used to process semiconductor wafers. Semiconductor wafers having undergone each processing step are stored in a FOUP (Front Opening Unified Pod), which is a semiconductor transport container, and then moved to the next step. A problem at this time is that the chemicals and gases used in the process remain as Airborne Molecular Contaminants (AMC) in the FOUP and permeate a resin forming the FOUP. These AMCs are gradually released from the FOUP over a long time to deteriorate elements and wiring on semiconductors or cause device troubles. For this reason, a material that does not allow gas to penetrate into the interior or a material that does not release the gas even if it penetrates is required as the polymer forming the FOUP.

### BRIEF DESCRIPTION OF THE DRAWINGS

FIG. 1 is a view illustrating a semiconductor wafer transport container of an embodiment.

FIG. 2 is a chart illustrating an energy diagram of a process in which TMA is oxidized by H₂O to form Al(OH)₃.

FIG. 3 is a chart illustrating a process in which HF is adsorbed onto Al(OH)₃.

FIG. 4 is a chart illustrating a process in which HCl is adsorbed onto Al(OH)₃.

FIG. 5 is a chart illustrating a process in which NH₃ is adsorbed onto Al(OH)₃.

FIG. 6A is a chart illustrating the result of an analysis of elemental composition distribution in a PC surface of an inner wall of a FOUP when temperature during exposure to TMA is set to 100° C. in Example 1.

FIG. 6B is a chart illustrating the result of an analysis of elemental composition distribution in a PC surface of an inner wall of a FOUP when temperature during exposure to TMA is set to 125° C. in Example 1.

FIG. 6C is a chart illustrating the result of an analysis of elemental composition distribution in a PC surface of an inner wall of a FOUP when temperature during exposure to TMA is set to 150° C. in Example 1.

FIG. 6D is a chart illustrating the result of an analysis of elemental composition distribution in a PC surface of an inner wall of a FOUP when temperature during exposure to TMA is set to 175° C. in Example 1.

FIG. 7A is a chart illustrating the result of an analysis of elemental composition distribution in a PC surface of an inner wall of a FOUP when temperature is set to 125° C. and TMA pressure is set to 100 Pa in Example 2.

FIG. 7B is a chart illustrating the result of an analysis of elemental composition distribution in a PC surface of an inner wall of a FOUP when temperature is set to 125° C. and TMA pressure is set to 300 Pa in Example 2.

FIG. 7C is a chart illustrating the result of an analysis of elemental composition distribution in a PC surface of an inner wall of a FOUP when temperature is set to 125° C. and TMA pressure is set to 900 Pa in Example 2.

FIG. 8A is a chart illustrating the result of an analysis of elemental composition distribution in a PC surface of an inner wall of a FOUP when temperature is set to 110° C. and TMA pressure is set to 100 Pa in Example 2.

FIG. 8B is a chart illustrating the result of an analysis of elemental composition distribution in a PC surface of an inner wall of a FOUP when temperature is set to 110° C. and TMA pressure is set to 300 Pa in Example 2.

FIG. 8C is a chart illustrating the result of an analysis of elemental composition distribution in a PC surface of an inner wall of a FOUP when temperature is set to 110° C. and TMA pressure is set to 900 Pa in Example 2.

FIG. 9A is a chart illustrating the result of an analysis of elemental composition distribution in a PC surface of an inner wall of a FOUP when temperature is set to 100° C. and TMA pressure is set to 300 Pa in Example 2.

FIG. 9B is a chart illustrating the result of an analysis of elemental composition distribution in a PC surface of an inner wall of a FOUP when temperature is set to 100° C. and TMA pressure is set to 900 Pa in Example 2.

FIG. 10A is a chart illustrating the result of the analysis of the elemental composition distribution in the PC surface of the inner wall of the FOUP before an HF exposure test in Example 4.

FIG. 10B is a chart illustrating the result of an analysis of elemental composition distribution in the PC surface of the inner wall of the FOUP after the HF exposure test in Example 4.

FIG. 11A is a chart illustrating the result (before an HF exposure test in Example 5) of an analysis of elemental composition distribution in a PC surface of an inner wall of a FOUP in Example 3A and Example 5.

FIG. 11B is a chart illustrating the result of an analysis of elemental composition distribution in the PC surface of the inner wall of the FOUP after the HF exposure test in Example 5.

FIG. 12 is a chart illustrating the result of an analysis of elemental composition distribution in a PC surface of an inner wall of a FOUP in Example 6.

### DETAILED DESCRIPTION

A semiconductor wafer transport container of an embodiment is a semiconductor wafer transport container including a resin container configured to store a semiconductor wafer, wherein a vicinity of a surface of a resin of at least an inner surface of the resin container is impregnated with aluminum oxide having a hydroxyl group, and a structure in which 1 atomic % or more of the aluminum oxide in terms of concentration of elemental aluminum is dispersed in the resin is present within at least a range of not less than 50 nm nor more than 10 μm in depth from the inner surface.

A semiconductor wafer transport container of embodiments will be hereinafter described with reference to the drawings. It should be noted that in the embodiments, substantially the same constituent parts are denoted by the same reference signs, and a description thereof may be partly omitted. The drawings are schematic, and a relation between thickness and planar dimensions, a thickness ratio among parts, and so on may be different from actual ones. Terms indicating up, down, and so on in the description indicate relative directions that are based on a case where a substrate surface of a semiconductor wafer stored in the later-described semiconductor wafer transport container is regarded as the upper side unless otherwise specified, and may differ from actual directions based on the gravitational acceleration direction.

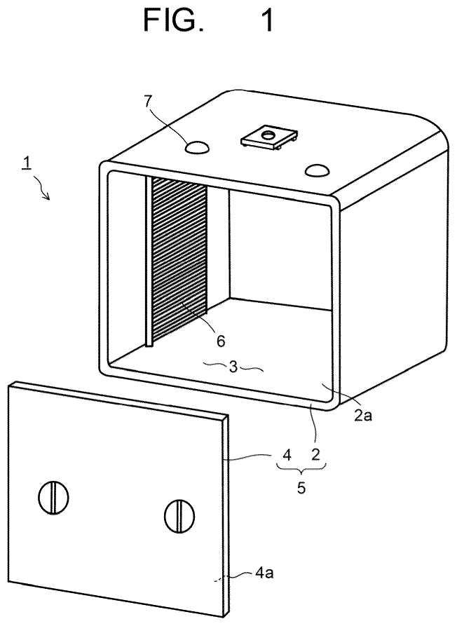

FIG. 1 illustrates an example of the semiconductor wafer transport container (FOUP) of the embodiments. The FOUP 1 illustrated in FIG. 1 includes a resin container main body 2 for storing semiconductor wafers. The resin container main body 2 has a shape with its front surface being open. A front opening part 3 of the resin container main body 2 can be closed by a resin door part 4. The FOUP 1 includes a resin container 5 composed of the resin container main body 2 and the resin door part 4. Inside the resin container main body 2, wafer supporting parts 6 to support the semiconductor wafers are provided. In FIG. 1, only the wafer supporting part 6 on one side is illustrated, but actually, the pair of wafer supporting parts 6 facing each other is provided, and such a pair of spaced wafer supporting parts 6 supports the not illustrated plurality of semiconductor wafers in parallel. The resin container main body 2 further includes gas inlets/outlets 7. As will be described later, surface treatment of the embodiments is applied to at least an inner wall (inner surface) 2a of the resin container main body 2 and an inner wall (inner surface) 4a of the resin door part 4.

As a resin material for FOUPs, a resin containing polycarbonate (PC) as a main component mixed with various materials is widely used. As a constituent material of the resin container 5 of the embodiments, PC is also used, for instance. PC exhibits excellent properties for use as a container owing to its suitable hardness and high glass transition temperature (Tg) of 175° C. On the other hand, PC is known as a resin having high gas permeability. The oxygen gas permeability of PC is 4700 cm³/m²·24 h·atm, and its water vapor permeability is 170 g/m²·24 h. These values are considerably large as compared with 80 cm³/m²·24 h atm and 20 g/m²·24 h of polyethylene terephthalate (PET) having a similar molecular structure. Because of such properties, it is highly permeable to AMC, which is a molecular contaminant, and this is considered to be the main reason why PC is easily contaminated with AMC.

The use of a resin with low AMC permeability instead of PC is also being considered. For example, in the case of polyetherimide (PEI), polar groups are arranged to achieve a high glass transition temperature (Tg) by polar immobilization, thereby physically retarding the diffusion rate of AMC. Further, in the case of a cyclic olefin polymer (COP), the solubility parameter (surface energy) of the resin is lowered to prevent AMC, which has high polarity and high surface energy, from being energetically miscible. FOUPs using these resins have also been in practical use. However, these resins are more difficult to synthesize than PC, which is a general-purpose resin, and as a result, tend to increase the price of the FOUPs.

To solve the aforesaid problems, in the semiconductor wafer transport container (FOUP) 1 of the embodiments, the resin forming the FOUP 1 is surface-treated, and only by this, the FOUP 1 free from AMC contamination is achieved. The surface treatment according to the embodiments is highly cost-effective for general-purpose resins such as PC, but is applicable to not only this but also most resins, and is compatible also with FOUPs 1 using the aforesaid PEI or COP.

In a first embodiment, AMC having once permeated the resin is immobilized so that it will not be released from the resin again. In a second embodiment, the surface of the resin material forming the FOUP is appropriately treated, thereby forming a protective film preventing AMC from penetrating into the resin. In a third embodiment, the resin surface is treated so as not to adsorb AMC molecules, and as a result, AMC is prevented from penetrating into the resin. These first embodiment to third embodiment can be combined. The embodiments will be detailed below.

### First Embodiment

As illustrated in FIG. 1, the semiconductor wafer transport container 1 of the first embodiment includes the resin container 5 composed of the resin container main body 2 for storing semiconductor wafers and the resin door part 4 for closing the front opening part 3 of the resin container main body 2. In the first embodiment, the vicinities of resin surfaces of at least the inner wall (inner surface) 2a of the resin container main body 2 and the inner wall (inner surface) 4a of the resin door part 4 are impregnated with aluminum oxide having hydroxyl groups (for example, AlOₓ+Al(OH)₃). Such aluminum oxide traps AMC (for example, HF, HCL, or NH₃) having penetrated into the resin container main body 2 and the resin door part 4 to prevent it from being released to the outside. For example, in the case where AMC is HF, AlOx+Al(OH)₃ with which the interior of the resin is impregnated captures F through an Al—F bond to prevent AMC (HF) having penetrated into the resin from being released.

The impregnation amount with the aluminum oxide having hydroxyl groups for capturing AMC is 1 atomic % or more in terms of the concentration of elemental aluminum with respect to the resin of the inner surface 2a of the resin container main body 2 and the inner surface 4a of the resin door part 4. Ranges (distribution ranges) impregnated with 1 atomic % or more of the aluminum oxide in terms of the concentration of elemental aluminum are present within ranges of not less than 50 nm nor more than 10 μm in depths from the surfaces of at least the inner surfaces 2a, 4a. Impregnating such ranges with 1 atomic % or more of the aluminum oxide having the hydroxyl groups in terms of the concentration of elemental aluminum makes it possible to obtain the ability to capture AMC (HF or the like) and accordingly prevent its release. The concentration of the aluminum oxide having the hydroxyl groups in the aforesaid impregnation ranges (distribution ranges) is preferably within a range of not less than 5 atomic % nor more than 30 atomic % in terms of the concentration of elemental aluminum. Impregnating the aforesaid impregnation ranges (distribution ranges) with 5 atomic % or more of the aluminum oxide in terms of the concentration of elemental aluminum makes it possible to more effectively obtain the ability to capture AMC and accordingly prevent its release. However, impregnating the aforesaid impregnation ranges (distribution ranges) with more than 30 atomic % of the aluminum oxide in terms of the concentration of elemental aluminum may deteriorate the inherent property of the resin. Accordingly, the characteristics such as handleability of the semiconductor wafer transport container (FOUP) 1 decrease.

In the first embodiment, the structure chemically inactivating AMC is formed in the resin forming the FOUP 1 as described above. A chemical compound (hereinafter, referred to as a trapping agent) inactivating AMC is present in the resin while being dispersed at a molecular level. Therefore, though diffusing in the resin, AMC having penetrated into the resin chemically bonds with the trapping agent present in the resin to be inactivated when encountering the trapping agent. At this time, since the trapping agent is dispersed at the molecular level, it instantly reacts with and immobilizes the AMC molecules when they approach it. Since the inactivated AMC does not turn into a gas again, it is immobilized in the resin and is not released from the resin.

To form the structure in which the trapping agent is dispersed in the resin, a vacuum apparatus using an atomic layer deposition (ALD) method is used. This apparatus is similar to an ALD apparatus, but is intended to impregnate the interior of the resin with a precursor of the trapping agent and does not deposit an atomic layer on a base material as is done in the later-described second embodiment. Therefore, the precursor exposure time is longer and the number of cycles is smaller than in typical ALD. The following experiment was conducted in an exposure mode in which a valve was closed after gas introduction and a pressure in this state was kept.

A sample is placed in a chamber and the pressure is reduced. In the case of the FOUP 1, the adsorption of AMC onto the inner wall of the FOUP 1 is a problem. The FOUP 1 has the gas outlets/inlets 7 for the introduction of an inert gas to its interior or for the pressure reduction of the interior. It is also possible to reduce the pressure through such gas outlets/inlets 7 of the FOUP 1 and form the trapping structure only on the inner wall of the FOUP 1. Bottles of the trapping agent raw material (precursor) and an oxidizing agent are placed, and the precursor is supplied into the pressure-reduced chamber or FOUP 1 to be made to permeate the resin. As the precursor, alkylaluminum is used. Being typically composed of a central metal and ligands, the precursor has low polarity and a low boiling point. Accordingly, it diffuses and permeates into the resin. When its permeation progresses to some extent, the supply is switched to the oxidizing agent. Then, the precursor reacts with the oxidizing agent to form metal (hydr)oxide. Since the precursor disperses and diffuses in the resin while being in the molecular state, it remains dispersed at the molecular level in the resin even if it is oxidized.

In many resins, by executing the above exposure only once, it is possible to form the dispersion structure of the trapping agent in the resin. Specifically, a polymer containing a carbonyl group in a resin chemical structure, such as PC, PEI, PET, or polymethylmethacrylate (PMMA), can be impregnated with a certain amount of the precursor by only single exposure because the precursor is physically adsorbed onto the vicinity of a lone electron pair of an oxygen atom of the carbonyl group. Oxidizing this precursor makes it possible to form a sufficient amount of the trapping agent. The same phenomenon occurs in groups other than the carbonyl group as long as they are groups having a lone electron pair, such as a cyano group, an amino group, and a nitro group.

The pressure of the precursor is preferably between 10 Pa and 5 kPa. If the pressure is lower than 10 Pa, a sufficient number of precursor molecules are not supplied, and a trapping layer is not sufficiently formed. On the other hand, if the pressure is higher than 5 kPa, the diffusion into the resin does not become uniform. In practice, a good trapping layer is formed when the pressure is between 50 Pa and 1 kPa. In the case where the resin is PC or PET, a large amount of gas is contained in PC or PET, and this gas reacts with the precursor on the surface. Therefore, if the pressure is lower than 10 Pa, precipitates are likely to form on the surface. Further, the exposure time is preferably 30 seconds or longer and is preferably 1 hour or shorter. More preferably, it is not shorter than 5 minutes nor longer than 20 minutes, and when the exposure time is within this range, a relatively uniform trapping layer is formed.

When the pressure of the precursor is low, the depth-direction distribution in the obtained trapping layer follows a diffusion equation, and when the pressure is high, it follows the molar content of the lone electron pair and therefore is substantially constant in the depth direction. The depth-direction thickness of the trapping layer is preferably not less than 50 nm nor more than 10 μm from the inner surface. If the thickness is less than 50 nm, a trapped amount cannot be sufficient. A large thickness does not pose a problem in trapping ability but necessitates too long a process time, leading to a production cost increase.

On the other hand, resins composed only of carbon atoms and hydrogen atoms, such as COP and polystyrene (PS), have no precursor adsorption site and thus are impregnated with only a small amount of the precursor. An alcohol group or a phenolic hydroxyl group does not adsorb it, either. When such resins are used, the above operation is conducted multiple times. At this time, in the case where trimethylaluminum (TMA/Al(CH₃)₃) is used as the precursor and oxidized by H₂O or the like to form AlOₓ or Al(OH)₃, as for the number of times of the exposure to the precursor, since there is no adsorption site in its molecular structure, AlOₓ or Al(OH)₃ that is to be a nucleus is first formed in the resin, and thereafter through several times of exposure, it is grown. In this case, since the amount of AlOₓ or Al(OH)₃ formed in the first exposure is small, the exposure is preferably repeated five times or more. The depth-direction thickness of the trapping layer in this case is not less than 50 nm nor more than 10 μm. If the thickness is less than 50 nm, the trapped amount cannot be sufficient. A large thickness does not pose a problem in trapping ability but necessitates too long a process time.

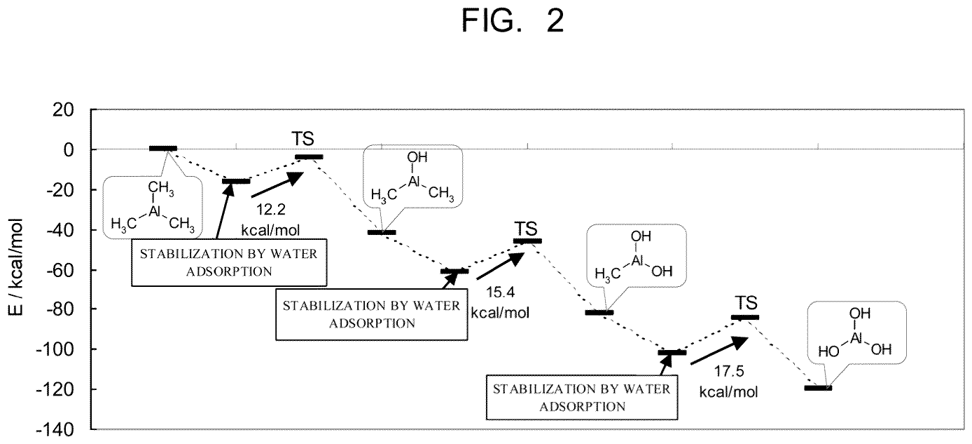

FIG. 2 illustrates an energy diagram of a process in which TMA is oxidized by H₂O to form Al(OH)₃. For this calculation, the density functional theory (DFT) program Gaussian was used, and as a functional, typical B3LYP/6-31G* was used. A reaction of TMA as the precursor of AlOₓ with H₂O was studied. TMA is oxidized even by H₂O in the ALD process. Note that ozone or plasma oxygen may be used for the oxidation. A state in which TMA diffuses in the resin to be isolated was assumed.

It is derived from the calculation that, in the process in which CH₃ ligands of TMA are oxidized by H₂O to be replaced by OH, barriers of transition states (TS) are present. The first barrier of the oxidation reaction was 12.2 kcal/mol, the second one was 15.4 kcal/mol, and the third one was 17.5 kcal/mol. If the barriers are to such a degree, it is considered that the reaction easily progresses only with slight heat, and Al(OH)₃ is finally formed. Further, even if the sample is left to stand at room temperature, it is considered that the reaction progresses under humidity in the air. Therefore, it is considered that aluminum (hydro)oxide formed in the resin by the TMA exposure stabilizes in the Al(OH)₃ form.

The precursor diffuses into the resin at the molecular level, and when it is thereafter exposed to the oxidizing agent, the reaction spontaneously progresses, and it turns into metal hydroxide as a reaction product. Since the reaction product has high polarity and also has a high boiling point, it cannot move in the resin and is immobilized in the resin in the state of dispersing at the molecular level.

The precursor is selected, for example, as follows, taking it into consideration that the trapping agent molecules chemically adsorb the AMC molecules. Since the trapping agent in the first embodiment is metal oxide, if binding energy between its metal and an element forming AMC is larger than binding energy between the metal and oxygen, AMC can be immobilized on the metal of the metal oxide. As AMC, mainly halogen atoms may be considered. Binding energies between various elements are described in the CRC Handbook of Chemistry and Physics 95th 2014-2015 and so on. The ligands of the precursor are closely related to the reactivity of the central metal, but the smaller their volume at the level at which they are not inadvertently oxidized, the more advantageous for the diffusion into the resin. Specific examples thereof include alkyl groups with 6 carbon atoms or less, such as a methyl group, an ethyl group, a propyl group, and a butyl group, and alkoxy groups with 6 carbon atoms or less, such as a methoxy group, an ethoxy group, a propoxy group, and a butoxy group.

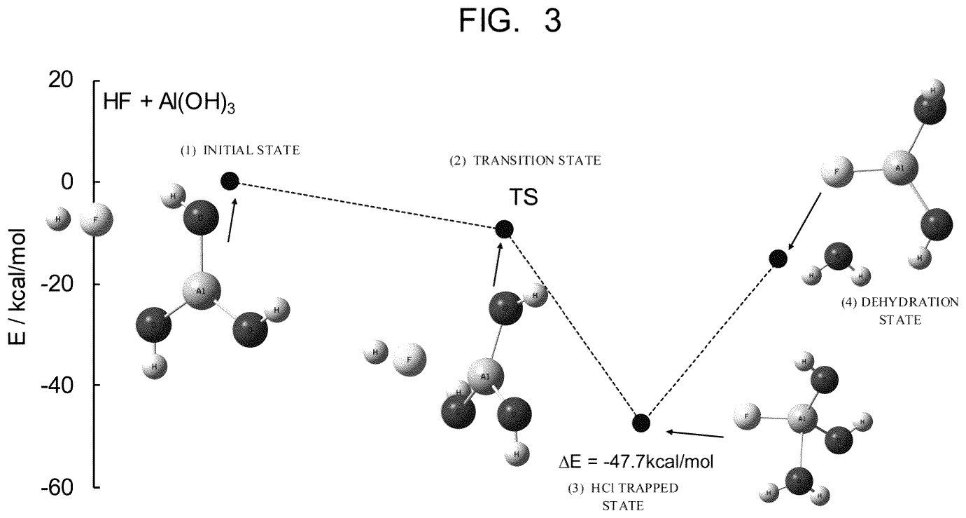

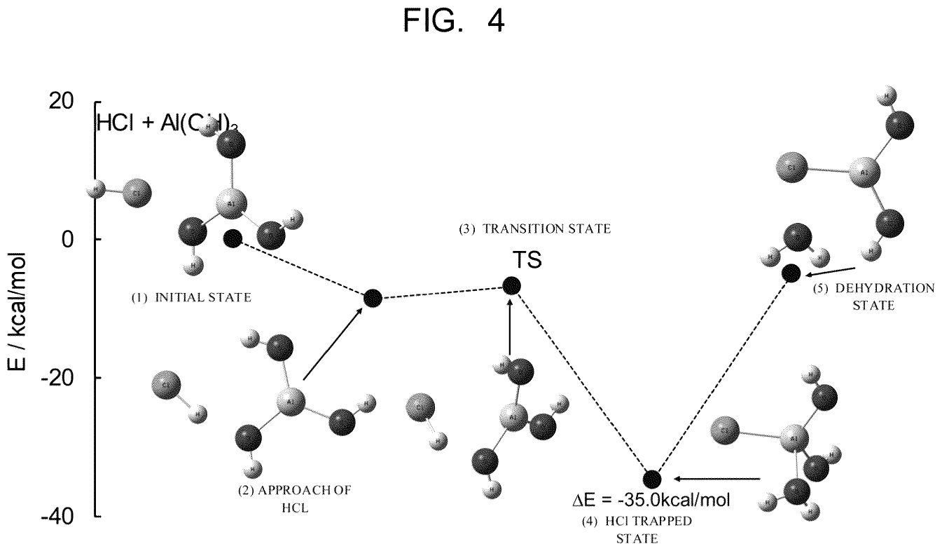

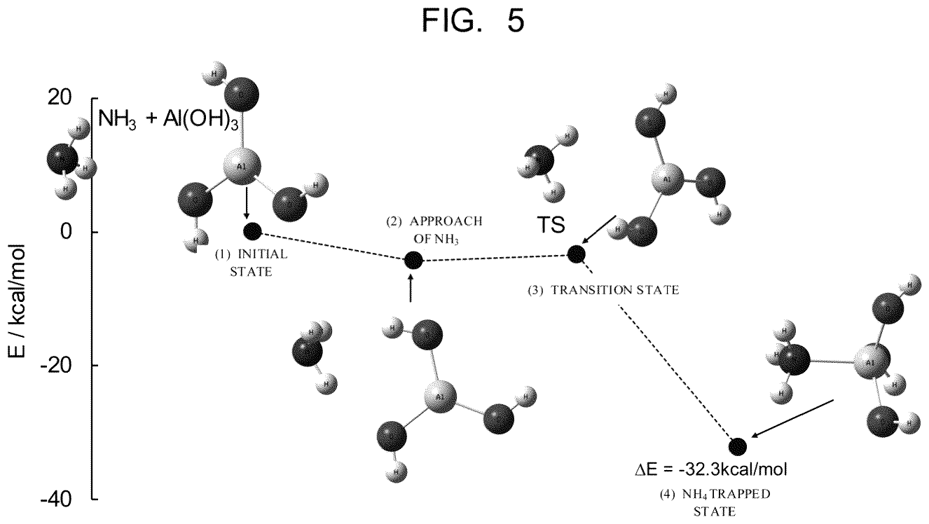

FIG. 3 illustrates a process in which hydrogen fluoride (HF), which is a main AMC, is adsorbed onto the trapping agent (Al(OH)₃). FIG. 4 illustrates a process in which hydrogen chloride (HCl), which is a main AMC, is adsorbed onto the trapping agent (Al(OH)₃). FIG. 5 illustrates a process in which ammonia (NH₃), which is a main AMC, is adsorbed onto the trapping agent (Al(OH)₃). Regarding AMC trapping ability, aluminum oxide or the like is used as a fluoride adsorbent in water treatment or the like, but not much information is available regarding other AMCs. For this reason, HF, HCl, and NH₃ were assumed as AMC, and reaction pathways of their adsorption onto Al(OH)₃ were calculated.

In the case of HF, as illustrated in FIG. 3, there is no barrier until a transition state is reached after HF directly approaches Al of Al(OH)₃. Further, since the energy in the state in which HF is trapped by Al(OH)₃ is −47.7 kcal/mol with respect to the initial state and thus is very deep, it is considered that the reaction progresses nonstop up to this point. For the subsequent separation into AlF(OH)₂ and H₂O, it is necessary to gain energy. This state is more stable than the initial state, but since F is most stable when trapped by Al(OH)₃, it is considered that the reaction stops in the trapped state.

In the case of HCl, as illustrated in FIG. 4, a shallow metastable state is present when HCl approaches Al(OH)₃, but since a barrier in a transition state is not very high, it is considered that the reaction continues to progress. Further, energy in a state in which HCl is trapped by Al(OH)₃ is −35.0 kcal/mol with respect to the initial state and thus is deep. As in the case of HF, for the separation into AlCl(OH)₂ and H₂O, it is necessary to gain energy. Since Cl is most stable in the state in which it is trapped by Al(OH)₃, it is considered that the reaction stops in the trapped state.

NH₃ is a base and thus presents a different picture. As illustrated in FIG. 5, a metastable state is present when NH₃ approaches Al(OH)₃, but since a barrier in a transition state is not very high, it is considered that the reaction continues to progress. The situation up to here is the same as in the case of HCl. Thereafter, NH₃ is trapped by Al(OH)₃ with the energy of −32.3 kcal/mol, and the reaction stops. Since materials that trap acid are typically basic, there is a concern over whether they are effective for NH₃, which is a base, but it is adsorbed owing to the unique property that Al(OH)₃ is amphoteric oxide.

From the above, it is expected that TMA made to react with H₂O in the resin forms Al(OH)₃ at the molecular level and has ability to trap HF, HCl, and NH₃. The first embodiment is based on the above principle. Based on a similar idea, it is considered that similar reactions progress even with other acids or bases. Further, since it is expected that even Group 13 metal elements undergo a similar reaction, Ga, In, Tl, and the like are also usable.

### Second Embodiment

As illustrated in FIG. 1, the semiconductor wafer transport container 1 of the second embodiment includes the resin container main body 2 for storing semiconductor wafers and the resin door part 4 for closing the front opening part 3 of the resin container main body 2. In the second embodiment, a metal oxide film is formed on at least the inner surface 2a of the resin container main body 2 and the inner surface 4a of the resin door part 4. The metal oxide film contains at least one selected from a group consisting of aluminum oxide, silicon oxide, and zirconium oxide. Such a metal oxide film is formed on each of the inner surface 2a of the resin container main body 2 and the inner surface 4a of the resin door part 4, with a mixture layer of the resin and the metal oxide therebetween.

The metal oxide film preferably has a thickness of not less than 20 nm nor more than 1 μm. Further, the mixture layer preferably has a thickness of not less than 10 nm nor more than 1 μm. Forming the metal oxide film on each of the inner surface 2a of the resin container main body 2 and the inner surface 4a of the resin door part 4 with the mixture layer of the resin and the metal oxide therebetween makes it possible to increase the adhesion of the metal oxide film. Accordingly, the metal oxide film functioning as a protective film against AMC can prevent AMC from penetrating into the resin.

In the second embodiment, appropriate treatment is applied to the surface of the resin material forming the FOUP 1 to form the protective film preventing the penetration of AMC into the resin as described above. Examples of a method for forming the protective film include chemical methods such as a chemical vapor deposition (CVD) method and an atomic layer deposition (ALD) method. According to such a method, unlike a physical method such as a PVD method, even if the inner wall of the FOUP 1 has irregular complicated structures, the formation of the protective film on shaded areas is not hindered. As a result, it is possible to conformally form the protective film of ceramic on the inner wall of the FOUP 1. At this time, the protective film can block AMC as long as it has a film thickness of 20 nm or more.

Note that the above-described forming method is substantially the same as the method in the first embodiment. Therefore, if the resin is exposed to the precursor in the same manner, the impregnation of the inside of the resin with the precursor progresses, and the precursor cannot be deposited as a film. PC widely used in FOUPs 1 has high gas permeability, and a protective film is not formed thereon. Therefore, in the case where ALD is used, alternate exposure to the precursor and the oxidizing agent for a short time is preferable. Consequently, though the precursor slightly penetrates into the resin in the first several cycles, it is possible to grow an oxide using an oxide generated near the resin surface as a starting point. The number of times the alternate exposure to the precursor and the oxidizing agent is repeated is preferably not less than 10 nor more than 1000. If the number of repetitions is less than 10, it is difficult to sufficiently grow the oxide. If the number of repetitions is over 1000, the metal oxide film becomes too thick and the process time becomes too long, leading to an increase in production cost.

A difference in process condition from the first embodiment is the exposure time per exposure, and it is preferably not less than 1 second nor more than 10 seconds. If it is longer than 10 seconds, the precursor seeps into the resin, making it difficult to obtain a firm protective film. If the exposure time is shorter than 1 second, the single exposure dose of the precursor is too small, making it difficult to sufficiently grow the oxide. Further, after the exposure to the precursor, it is preferable to expose it to the oxidizing agent for 10 seconds or less to oxidize and immobilize the precursor. This enables the sufficient growth of the oxide. Repeating this multiple times makes it possible to form a thin film of the metal oxide on the resin surface. Further, a pressure at the time of the exposure to the precursor is preferably not less than 1 Pa nor more than 300 Pa. If the pressure at the time of the exposure is less than 1 Pa, a sufficient amount of the precursor is not supplied, and the formability of the metal oxide becomes poor, making it difficult to grow the metal oxide. If the pressure at the time of the exposure is over 300 Pa, the precursor tends to penetrate into the resin, making it difficult to sufficiently grow the firm metal oxide. To increase the purity of the metal oxide to improve film quality, the pressure at the time of the exposure to the precursor is more preferably 100 Pa or less. After the exposure to the precursor, the precursor is discharged, and the oxidizing agent is introduced. As the oxidizing agent, water, ozone, or plasma oxygen is used. Next, the oxidizing agent is discharged. This is set as one cycle, which is repeatedly executed. After the precursor and the oxidizing agent are discharged, an argon gas or the like may be introduced. This process does not depend on the composition of the resin, unlike the first embodiment.

The material of the protective film formed by the surface treatment is at least one selected from aluminum oxide, silicon oxide, and zirconia oxide. As a material for forming such metal oxide, at least one selected from alkyl metal, alkoxy metal, and alkylamino metal is used. Examples of a precursor of the aluminum oxide include trialkylaluminum and trialkoxyaluminum, having an alkyl group with not less than 1 nor more than 6 carbon atoms. Examples of a precursor of the silicon oxide include bis(alkylamino)silane, aminoalkyltrialkoxysilane, tetraalkoxysilane, trialkoxysilanol, trialkylsilane, and tris(dialkylamino)silane, having an alkyl group with not less than 1 nor more than 6 carbon atoms. Examples of a precursor of the zirconium oxide include tetrakis(dialkylamino)zirconium and zirconium(IV)alkoxide, having an alkyl group with not less than 1 nor more than 6 carbon atoms. Examples of the alkyl group with not less than 1 nor more than 6 carbon atoms include a methyl group, an ethyl group, a propyl group, and a butyl group. In the case where a plurality of alkyl groups are attached, alkyl groups having different numbers of carbon atoms may be attached. Further, the alkyl group may have a branch.

The protective film formed by the resin surface treatment method in the second embodiment is preferably a metal oxide film having a thickness of not less than 20 nm nor more than 1 μm. The protective film, if its thickness is less than 20 nm, has poor AMC blockability. If the thickness of the protective film is over 1 μm, though the AMC blockability is sufficient, peeling or the like is likely to occur and the process time becomes too long, leading to an increase in production cost. Further, the metal oxide film is formed, with the resin-metal oxide mixture layer having a not less than 10 nm nor more than 1 μm thickness being present between itself and the surface. Forming such a mixture layer spatially alleviates a surface energy difference between the resin and the metal oxide, enabling firm adhesion. It is possible to determine the thickness of the mixture layer by executing an element analysis while etching is performed.

In the surface treatment of the resin, the reaction temperatures of various precursors are preferably low. For example, in the case of trialkylaluminum, which is the aluminum precursor, since the binding energy of an Al atom and a C atom is 267.7 kJ/mol, the reaction occurs even at about 100° C. Therefore, the reaction can occur at relatively low temperatures within a range of the heatproof temperatures of most resins forming FOUPs 1. On the other hand, since the binding energy of a Si atom or a Zr atom with a C atom is higher than the binding energy of an Al atom and a C atom, there is a possibility that the reaction temperature becomes as high as 200° or higher, for instance. Therefore, in some cases, a usable resin may be limited. In view of this, the use of aluminum oxide is more preferable.

Further, since AMC contains HF, silicon oxide may react with HF and partly volatilize to come off the surface of the protective film. Therefore, as the protective film, aluminum oxide is preferred to silicon oxide. Further, forming the protective film of the second embodiment after forming the trapping structure of the first embodiment on the resin surface produces a synergistic effect, leading to a higher effect of preventing AMC contamination.

### Third Embodiment

As illustrated in FIG. 1, the semiconductor wafer transport container 1 of the third embodiment includes the resin container main body 2 for storing semiconductor wafers and the resin door part 4 for closing the front opening part 3 of the resin container main body 2. In the third embodiment, on at least the inner surface 2a of the resin container main body 2 and the inner surface 4a of the door part 4, a self-assembled monolayer (SAM) having an alkyl group with not less than 8 nor more than 32 carbon atoms is provided. Such a SAM can reduce the adsorption of AMC molecules. Therefore, the penetration of the AMC molecules into the resin can be prevented.

In the third embodiment, as described above, the treatment is applied to the resin surface to prevent the adsorption of the AMC molecules so that AMC does not permeate into the resin. Regarding a process in which the AMC molecules penetrate into the resin, it is known that their adsorption onto the resin surface occurs as a first stage. One solution would be to reduce the surface energy of a polymeric material forming the resin, but changing the material itself is difficult and costs high.

The AMC molecules are high in surface energy because they are ionic or polar molecules of HF, HCl, NH₃, or the like. Many of the typical general-purpose resins have polar groups such as carboxyl groups, hydroxyl groups, or ester groups in the chemical structures of the polymers. Since they are immobilized by Coulomb force or a hydrogen bond, rigidity improves. Therefore, if the polar groups are present in these resins, AMC is easily attracted thereto. On the other hand, lowering the surface energy of the resin surface prevents the adsorption of the AMC molecules onto the resin surface. If the AMC molecules are not present on the surface, their diffusion to the inside does not occur, either.

However, a method for changing the resin surface from a high polarity state to a low polarity state is limited. In the third embodiment, a method to lower the surface energy of only the resin surface by surface treatment is used. As a material for forming the SAM, alkylamine, alkylphosphonic acid, alkylalkoxysilane, or the like is used. A resin having an ester group, such as PET or PC, can be hydrophobized through a reaction of alkylamine with the ester. In the case where alkylamine is thus used, it is possible to bond its alkyl group to the resin through an amide bond. Further, in the case where alkylalkoxysilane or the like is used, by the resin containing a hydroxyl group in its chemical structure, the alkyl group can be disposed on the resin surface.

If the number of carbon atoms in the alkyl group of alkylamine, alkylalkoxysilane, or alkylphosphonic acid is too small, the effect of reducing the adsorption of the AMC molecules decreases. In view of this, as the material for forming the SAM, it is preferable to use a material that has an alkyl group with a large number of carbon atoms, for example, an alkyl group with not less than 8 nor more than 32 carbon atoms and that has a low vapor pressure. Examples of alkylalkoxysilane include alkyltrialkoxysilane, alkylmethyldialkoxysilane, alkylethyldialkoxysilane, alkyldimethylmonoalkoxysilane, and alkyldiethylmonoalkoxysilane, containing an alkoxy group with 1 or 2 carbon atoms and an alkyl group with not less than 8 nor more than 32 carbon atoms. For example, in the case where the resin contains the hydroxyl group in its chemical structure, the resin surface can be hydrophobized by alkylalkoxysilane containing an alkyl group with 8 or more carbon atoms, such as octyltrimethoxysilane.

The surface treatment by the SAM of the third embodiment is applicable in combination with the first embodiment or the second embodiment. In the case of the application of the third embodiment in combination with the first embodiment, causing the adsorption or the like of the SAM onto the aluminum (hydr)oxide present in the resin or also the resin surface results in the hydrophobization of the resin surface, making the adsorption of the AMC molecules more difficult. In the case of the application of the third embodiment in combination with the second embodiment, making the SAM adsorbed onto the metal oxide film surface results in the hydrophobization of the metal oxide film surface, making the adsorption of the AMC molecules difficult. Therefore, it is possible to more effectively reduce the diffusion of the AMC molecules into the resin. For example, in the case where alkylphosphonic acid is used as the material for forming the SAM, its alkyl group is bonded to the metal oxide such as aluminum oxide through a phosphonate ester bond. In the case of alkylalkoxysilane, its alkyl group is bonded to the metal oxide by a siloxane bond. Owing to these, it is possible to more effectively reduce the diffusion of the AMC molecules into the resin.

As described above, in the case where a structure having aluminum oxide, silicon oxide, or the like is formed in the first embodiment or the second embodiment, molecules corresponding to these can be chemically adsorbed or physically adsorbed. Specifically, in the case of aluminum oxide, by chemically adsorbing alkylphosphonic acid, it is possible to bond its alkyl group to the aluminum oxide through the aforesaid phosphonate ester bond, making it possible to form a stable hydrophobic surface. Further, in the case of silicon oxide, by chemically adsorbing alkylalkoxysilane such as alkyltrimethoxysilane or alkylmonomethoxysilane, it is possible to bond its alkyl group to the silicon oxide through a siloxane bond, making it possible to form a stable hydrophobic surface. The combination of the aluminum oxide and the alkelphosphonic acid can form molecules with a high density of about 1×10¹⁴ pieces/cm², which is especially effective for preventing the penetration of the AMC molecules.

The chain length of the alkyl group of the alkyl SAM may be 8 or more in terms of the number of carbon atoms. An alkyl group with 8 carbon atoms has a chain length of about 1 nm. An intermolecular interaction is determined by the overlap of electron clouds (wave functions), that is, the intermolecular distance, and this interaction decays substantially according to an exponential function. If the chain length of the alkyl group is less than 1 nm, it is difficult to block the influence of the surface energy of the lower-layer resin. Therefore, by forming the SAM using alkylamine, alkylalkoxysilane, or alkylphosphonic acid that has an alkyl group with 8 or more carbon atoms, it is possible to favorably prevent the adsorption of the AMC molecules onto the resin surface. The number of carbon atoms in the alkyl group is more preferably 12 or more.

It is thought that the blocking effect is higher as the chain length of the alkyl group is longer if the chain is straight. However, since the alkyl chain bends, closest packing is difficult, and as the chain length is longer, a packing factor of the SAM decreases. Therefore, the upper limit of the number of carbon atoms is about 40 and is preferably 32 or less. If the number of carbon atoms is equal to or larger than this, a bending effect or the like of the alkyl chain known in a polyethylene crystal or the like occurs, resulting in a decreased packing factor. Generally, the number of carbon atoms is preferably 24 or less also in view of synthesis.

Further, to improve the SAM packing factor, two kinds or more of SAMs different in alkyl chain length are sometimes mixed. For example, if an alkyl SAM with 24 carbon atoms is adsorbed, a defect that the SAM is not adsorbed may occur. By making this adsorb an alkyl SAM with 12 carbon atoms, it is also possible to prevent the occurrence of the defect.

### EXAMPLES

Next, Examples and their evaluation results will be described.

### Example 1

FOUPs whose main components were PC were prepared and installed in a vacuum chamber. A step of exposure to trimethylaluminum (TMA), which is a precursor of aluminum oxide (AlOₓ), and a step of subsequent exposure to H₂O to generate aluminum oxide were executed, thereby attempting to form the aluminum oxide near the PC surfaces. Under varied TMA exposure temperatures of 100° C., 125° C., 150° C., and 175° C., a layer of the aluminum oxide was formed on an inner wall of each of the FOUPs. The exposure time to TMA was set to 600 seconds.

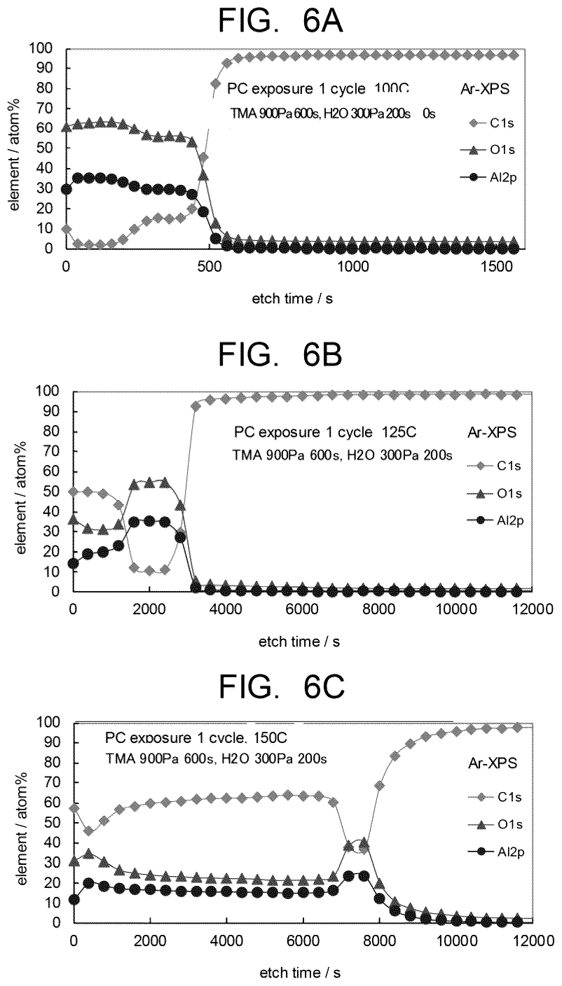

Parts of the FOUPs were cut out, and elemental composition distributions formed in the PC surfaces of the inner walls of the FOUPs were measured by X-ray photoelectron spectroscopy (XPS) using argon sputtering. This method will be hereinafter referred to as Ar-XPS. FIG. 6A to FIG. 6D illustrate the results of the Ar-XPS analyses under the respective TMA exposure temperatures. At 100° C., an AlOₓ monolayer was formed on a surface layer, and thereunder, a layer (mixture layer) in which AlOₓ is dispersed in PC was formed. Further, at 150° C., an AlOₓ dispersion layer with about 1 μm was formed. At 125° C., a structure that is basically the same as that at 150° C. but has a shorter Al diffusion length was confirmed. From these, it is inferred that a boundary between a mode in which AlOₓ is formed on the surface layer and a mode in which it is dispersed inside is between 100° C. and 125° C. However, something like a “diffusion front” of AlOₓ, which was recognized at 150° C., was also clearly detected at 125° C. At 175° C., which is higher than the glass transition temperature (Tg), Al was detected in a range up to a several μm depth, indicating that the diffusion rate greatly increased. This is a reasonable result because, at Tg or higher, the motion of molecules of the main chain of a polymer chain of the resin occurs. Note that the PC board had a trace of partial melting and had many cracks formed during a shrinkage process, and accordingly, Tg is the upper limit temperature.

To understand the thermal properties of the PC resins used as the samples, differential scanning calorimetry (DSC) and thermogravimetry (TG) were conducted. A literature value of Tg of PC is 174° C., but Tg measured in the PC resins by DSC this time was 150° C. The difference between Tg this time and the literature value is considered to be due to the molecular weight of PC. Tg reaches the prescribed value (literature value) when the molecular weight is 100,000 or more, but lowers when the molecular weight is equal to or less than that. Further, their thermal decomposition temperatures measured in TG were 460° C. This leads to an understanding that this PC softens at over 150° C. but is not thermally decomposed at temperatures up to 460° C.

From the results of the DSC measurement and the AlOₓ impregnation experiment using TMA, it has been confirmed that it is possible to disperse AlOₓ in PC even at Tg or lower. Here, regarding the condition enabling the formation of the AlOₓ film on the PC surface and the condition enabling the formation of the Al(OH)₃ dispersion structure inside PC, the process temperature at the time of the exposure of the PC surface to the precursor of AlOₓ is preferably not lower than 100° C. nor higher than 125° C.

That is, to maintain the shape of the actual FOUP, the process temperature is preferably sufficiently lower than the softening temperature of the resin, and is preferably equal to or lower than a temperature that is still lower than Tg and does not cause a dimensional error of the FOUP. In Example 1, dimensional variation was observed at 150° C., but no dimensional variation was observed at 125° C. At Tg or lower, it is thought that the diffusion of the precursor in the resin is slow, but according to the results of the DSC measurement and the AlOₓ impregnation experiment using TMA, it is possible to sufficiently disperse AlOₓ in PC as described above; therefore, the upper limit of the process temperature is preferably set to 125° C. The results of the Ar-XPS measurement of the elemental composition distributions formed in the PC surfaces showed that the AlOₓ monolayer was formed on the surface layer at a low temperature, and the AlOₓ dispersion layer was formed at high temperatures. At still lower temperatures, needle crystals occurred on the PC surface. They may scatter in the FOUP to be a contamination source as waste. Therefore, regarding the condition enabling the formation of the AlOₓ film on the PC surface and the condition enabling the formation of the Al(OH)₃ dispersion structure in PC, the lower limit of the process temperature when the PC surface is exposed to the precursor of AlOₓ is preferably 100° C.

### Example 2

Under TMA exposure temperatures in a narrower range of 100 to 125° C. and varied TMA pressures of 100 Pa, 300 Pa, and 900 Pa, PC surface treatment was conducted by the same method as in Example 1. The exposure time to TMA was set to 600 seconds. While these samples were Ar-etched, their depth-direction elemental compositions were measured by Ar-XPS.

From the elemental distributions, it is seen that at 125° C., C and Al coexist on the surface and Al is dispersed in PC. It is inferred that TMA diffuses in PC in the state of TMA, and thereafter is oxidized by H₂O or the like to be converted to Al(OH)₃, which then disperses and is immobilized. The amount of Al increases as the pressure becomes higher. At a low pressure, the distribution followed a diffusion function, but at a high pressure, the distribution was flat. This is considered to be because TMA in the diffusion process diffuses while hopping carbonyl groups of PC, and accordingly, the distribution is regulated by the density of the carbonyl groups.

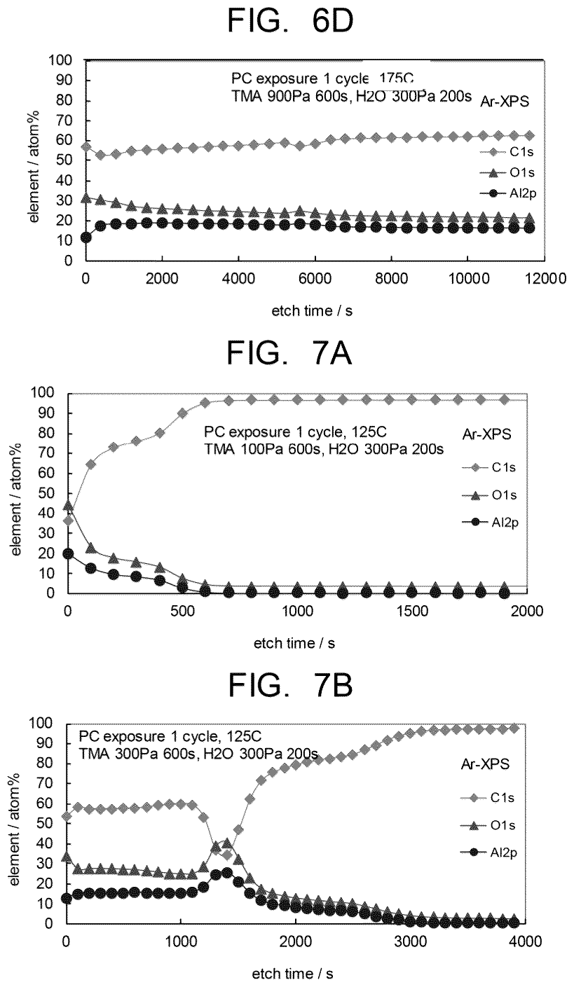

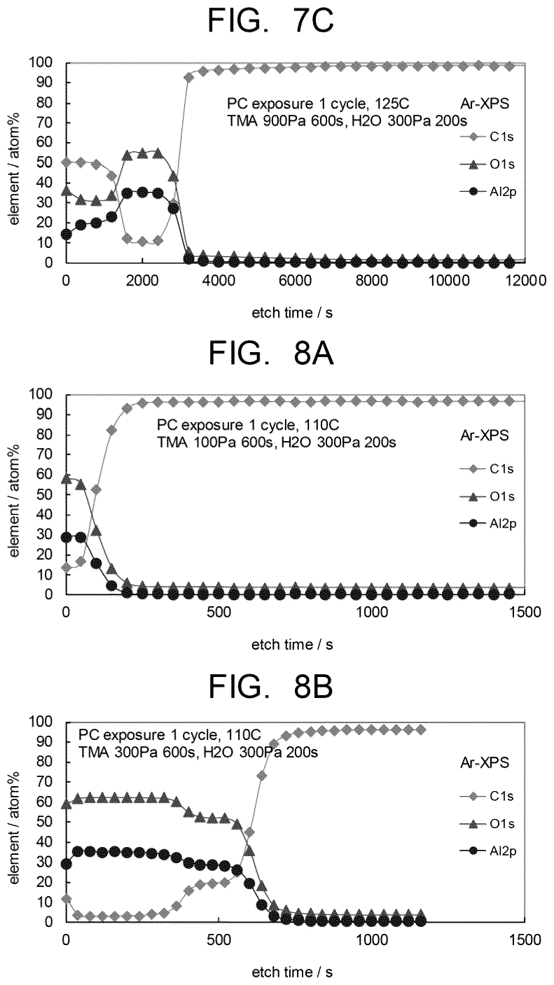

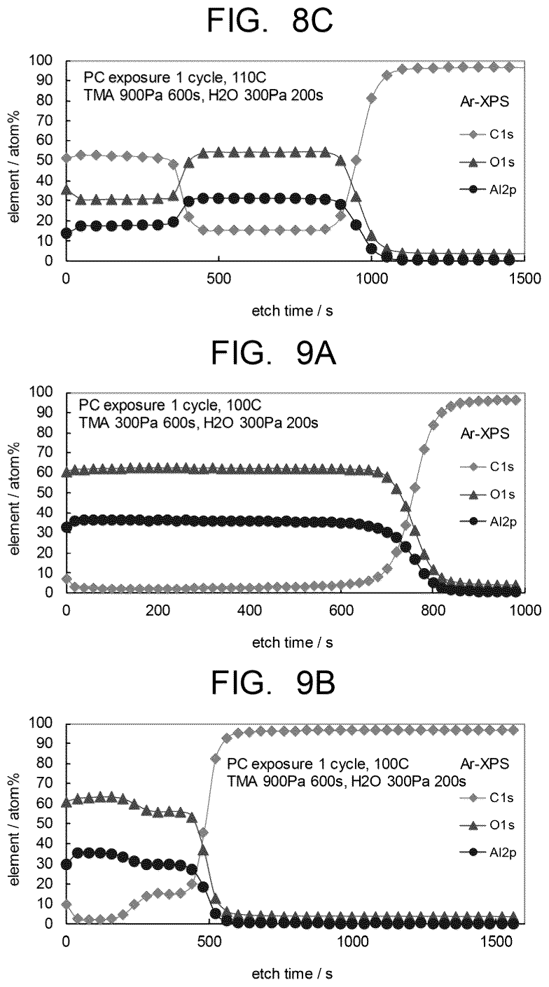

FIG. 7A to FIG. 7C, FIG. 8A to FIG. 8C, and FIG. 9A to FIG. 9B illustrate the results of the Ar-XPS analyses under the TMA exposure temperatures and the TMA pressures. At 110° C., a film made up only of AlOₓ was formed on the outermost surface when the TMA pressure was 300 Pa. Based on the 350-second Ar etching time, it is estimated that the AlOₓ film with about 70 nm was formed. Thereunder, the structure in which Al(OH)₃ was dispersed in PC, which structure was seen at high temperatures, was also seen. Further, a high Al-concentration layer ascribable to a diffusion front was observed at a deep place. At 100° C., an AlOₓ film with a thickness corresponding to about 700-second sputtering time (140 nm) was formed on the outermost surface when the TMA pressure was 300 Pa. At 900 Pa, an AlOₓ layer was thinner, and a layer of PC mixed with Al(OH)₃ was observed. When the pressure was 900 Pa, the AlOₓ layer on the surface was thinner, and an Al(OH)₃ dispersion structure was formed in PC.

To summarize the above, aluminum (hydr)oxide forms the AlOₓ layer as the protective film, the low-concentration dispersion layer of Al(OH)₃ as the mixture layer, and the high-concentration dispersion layer of Al(OH)₃ in order from the surface. The formation of the AlOₓ layer as the protective film is prominent in the case of low-temperature·low-pressure TMA, and is not observed under the high-temperature condition. Contrarily, the Al(OH)₃ dispersion layer in PC tends to be thick at high temperatures. Further, the high-concentration Al(OH)₃ layer whose Al concentration is over 20 atomic % is formed at a deep place under the high TMA pressure condition.

### Example 3A

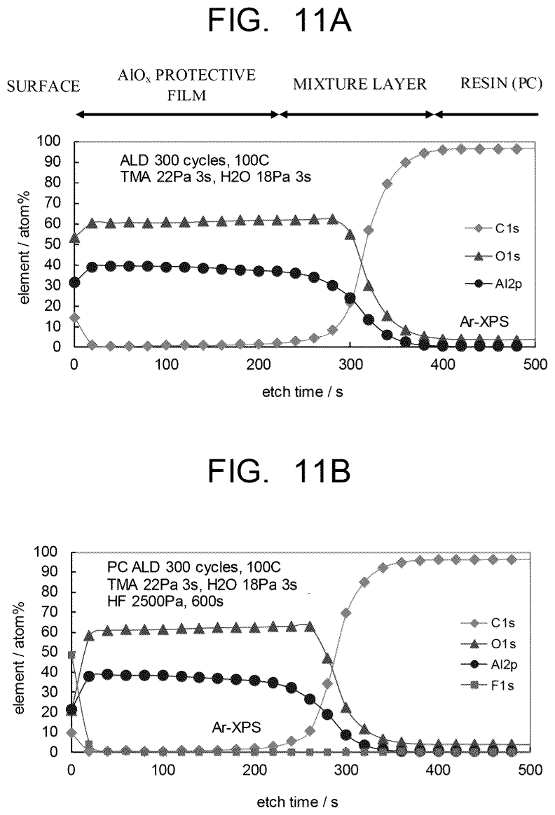

As in Example 1, a FOUP whose main component was PC was prepared. In an ALD chamber, film formation was performed in an ALD mode which is a chemical method in which this is exposed 300 times alternately (every three seconds) to TMA, which is a precursor of aluminum, and H₂O, which is an oxidizing agent. The temperature of the FOUP at this time was set to 100° C. TMA easily permeates PC, and therefore, in the ALD mode (specimen 1), the short-time exposure and oxidation are repeated so that an AlOₓ film with a high density can be easily formed as a protective film on the surface layer. On the other hand, in an impregnation mode (TMA impregnation mode) (specimen 2), it is thought that TMA penetrates into PC by the long time exposure only to TMA, and AlOₓ is sparsely formed in PC by the subsequent oxidation. While these samples were Ar-sputtered, their depth-direction elemental distributions were observed using Ar-XPS. In the ALD mode (specimen 1), it was confirmed that the AlOₓ film was formed as the protective film on the surface layer. FIG. 11A is a chart illustrating the result of an analysis of elemental composition distribution in the PC surface side of an inner wall of the FOUP of the specimen 1. As illustrated in FIG. 11A, the AlOₓ protective film is formed on the PC surface side and a mixture layer of AlOₓ and PC is formed between the AlOₓ protective film and PC. The film thickness of AlOₓ is 70 nm when the etching time is 300 seconds. Regarding Al₂O₃ formed on a Si substrate under the same condition, the etching time was 180 seconds, and in measurement by an ellipsometer, its thickness was 25.6 nm, and thus that on PC is slightly thicker. Basically, it can be considered that an AlOₓ dense structure was formed.

### Example 3B

A FOUP whose main component was PC was prepared and installed in a vacuum chamber. It was attempted to form Si oxide near a PC surface in an ALD mode, which is a chemical method in which exposure to bis(ethyl-methyl-amino)silane (BEMAS), which is a precursor of silicon, and the subsequent exposure to O₃, which is an oxidizing agent, are repeated alternately (every three seconds) 100 times. At a 140° C. BEMAS exposure temperature, a Si oxide layer was formed on an inner wall of the FOUP. Part of the FOUP was cut out, and elemental composition distribution formed in the PC surface of the inner wall of the FOUP was measured by Ar-XPS. The result showed that a SiO₂ monolayer was formed on the surface layer, and thereunder, a layer of SiO₂ dispersed in PC was formed.

### Example 4

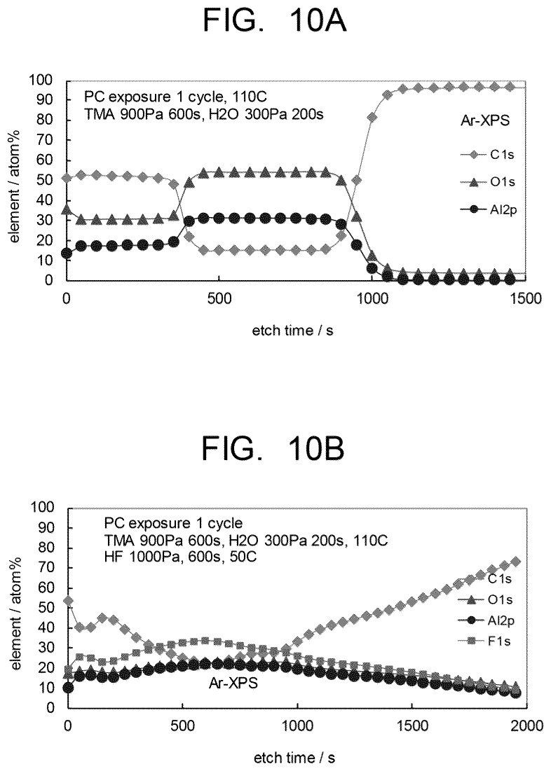

An HF exposure test was conducted on the FOUP, obtained in Example 2, on whose inner wall the Al(OH)₃ impregnation structure was formed. The same apparatus as that in Example 1 was used in the test. The FOUP, obtained in Example 2, on whose inner wall the Al(OH)₃ trapping layer was formed was set and exposed to HF for 10 minutes under a 1000 Pa pressure. This is an acceleration experiment in which the above condition is several-digit larger as compared with the ppb order of the AMC concentration. This FOUP was taken out, part of the FOUP was cut out, and elemental composition distribution formed in the PC surface of the inner wall of the FOUP was measured by Ar-XPS. FIG. 10A is a chart illustrating the result of an analysis of the elemental composition distribution in the PC surface of the inner wall of the FOUP before the HF exposure test, and FIG. 10B is a chart illustrating the result of an analysis of the elemental composition distribution in the PC surface of the inner wall of the FOUP after the HF exposure test. Near the surface, signals of F in addition to Al were detected. In Ar-XPS, elements O, N, and F bonded to or dissolved in the resin should not be detected in principle because they are sputtered out by the Ar sputtering. Therefore, it is seen that the F atoms detected in this measurement are F atoms bonded to Al. As described above, it has been confirmed that Al(OH)₃ formed in the resin is trapping HF.

### Example 5

An HF exposure test was conducted on the FOUP, obtained in Example 3, on whose inner wall the AlOₓ film was formed. The same apparatus as that used in Example 1 was used in the test. The FOUP, obtained in Example 3, on whose inner wall the AlOₓ film was formed was set and exposed to HF for 10 minutes under a 2500 Pa pressure. This FOUP was taken out, part of the FOUP was cut out, and elemental composition distribution formed in a PC surface of the inner wall of the FOUP was measured by Ar-XPS. FIG. 11A is a chart illustrating the result of an analysis of the elemental composition distribution in the PC surface side of the inner wall of the FOUP before the HF exposure test. As illustrated in FIG. 11A, the AlOₓ protective film is formed on the PC surface side, and the mixture layer of AlOₓ and PC is formed between the AlOₓ protective film and PC. FIG. 11B is a chart illustrating the result of an analysis of the elemental composition distribution in the PC surface side of the FOUP inner wall after the HF exposure test. Only in a several nm range from the surface, signals of F were detected. In most of the AlOₓ (Al₂O₃) layer thereunder, F was not detected. This indicates that, owing to the formation of the AlOₓ dense film, O in only Al on the outermost surface was replaced by F, but HF did not penetrate up to the inside of the AlOₓ film.

As described above, it has been confirmed that the AlOₓ film formed on the resin surface functions as the protective film that blocks HF. Further, the result that the F atoms are detected only near the surface and do not penetrate to the inside shows that even 100 times is sufficient as the number of times of the exposure in Example 3.

### Example 6

A FOUP whose main component was PC was prepared and installed in a vacuum chamber. It was attempted to form aluminum oxide near the PC surface by executing a step of exposure to trimethylaluminum (TMA), which is a precursor of aluminum oxide (AlOₓ), and a step of subsequent exposure to H₂O to produce aluminum oxide. The temperature during the TMA exposure was set to 100° C., and a layer of aluminum oxide was formed on an inner wall of the FOUP. The TMA exposure time was set to 600 seconds. In this process (impregnation mode), by the long-time exposure only to TMA, TMA was made to permeate into PC, and by the subsequent oxidation, AlOₓ was sparsely formed in PC. Further, without taking out the FOUP from the chamber, a film was formed in the ALD mode, which is a chemical method in which the exposure to TMA, which is an aluminum precursor, and the exposure to H₂O, which is an oxidizing agent, were alternately (every three seconds) executed 150 times. In the ALD mode, by repeating the short-time exposure and oxidation, a dense AlOₓ film is easily formed on the surface layer.

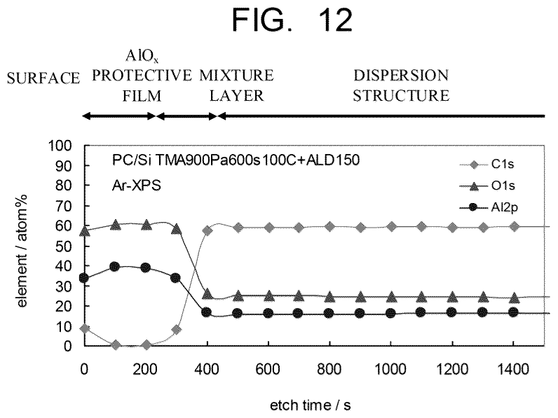

FIG. 12 illustrates the result obtained when depth-direction elemental distribution in the obtained sample was observed while it was Ar-sputtered using Ar-XPS. As illustrated in FIG. 12, a firm protective film made up of AlOₓ was formed on the surface layer. It is expected that the protective film plays a role in hindering the penetration of AMC. Further, a mixture layer in which the Al concentration decreased with a gradient was formed. Unlike a ceramic film formed on a resin by a typical physical film formation such as vapor deposition or sputtering, this layer is made up of a mixture of the resin and the material of the protective film to play the role of an adhesive layer, and accordingly the protective film is less likely to peel. Thereunder, a resin layer having an Al(OH)₃dispersion structure is further present. Even if AMC passes through the protective film, it is trapped and immobilized on the dispersion structure layer. Note that there is a layer only of the resin under the dispersion structure though it does not fall within the range of the drawing.

Such a structure having both the protective film and the dispersion structure has a very high effect of preventing AMC penetration and a very high characteristic of preventing AMC from being released because the blocking ability of the protective film and the trapping ability of the dispersion structure are kept as they are.

### Example 7

In Example 7, surface treatment with a SAM was executed. FOUPs whose main components were PC were prepared. Octadecyltrimethoxysilane was put in a 1 mL petri dish, and the petri dish was placed in the FOUP, followed by sealing. After 24 hours passed, the octadecyltrimethoxysilane was taken out. A sample obtained through a reaction of the octadecyltrimethoxysilane with an inner wall of the FOUP is a sample A.

A 5 mass % ethanol solution of dodecylamine was prepared. After this solution was poured into the FOUP, followed by sealing, the whole FOUP was heated to 60° C. and left to stand for 30 minutes. After the ethanol solution of dodecylamine was discharged, rinsing with ethanol was performed twice, and washing with water was further performed. This is a sample B.

A 1 mass % ethanol solution of octadecylamine was prepared. After this solution was poured into the FOUP, followed by sealing, the whole FOUP was heated to 70° C. and left to stand for 30 minutes. After the ethanol solution of octadecylamine was discharged, rinsing with ethanol was performed twice, and washing with water was further performed. This is a sample C.

The water contact angles of the inner walls of these FOUPs were measured. The drop contact angle of an untreated sample was 90°, while the drop contact angle of the sample A was 98.5°, the drop contact angle of the sample B was 125.8°, and the drop contact angle of the sample C was 99.5°. It is seen that surface hydrophobicity increased after the treatment in all of the samples.

Next, an HF exposure test was conducted on the FOUPs whose inner walls were treated. The same apparatus as that in Example 4 was used in the test. PCs having undergone the exposure test were partly cut out, and elemental compositions in their outermost surfaces were observed by XPS. The result showed that the content of F atoms in the resin surface of the untreated sample was 21 atomic %. On the other hand, the content of F atoms was 5.2 atomic % in the sample A, 1.2 atomic % in the sample B, and 3.2 atomic % in the sample C. It has been confirmed that owing to the surface treatment of the resin surfaces with the SAM, the surfaces were hydrophobized and adsorbed a less amount of F elements having high polarity.

### Example 8

The FOUP, fabricated in Example 2, in which the Al(OH)₃ dispersion structure was formed inside the resin near the resin surface layer was prepared. This is a sample D. Further, the FOUP, fabricated in Example 3, on whose surface layer the AlOₓ film was formed was prepared. This is a sample E. The water contact angles of inner walls of these FOUPs were measured. The drop contact angle of the sample D was 87.2°, and the drop contact angle of the sample E was 87.9°.

Next, a solution in which octadecylphosphonic acid was dissolved in ethanol with a 10 mmol/L concentration was prepared. After this solution was poured into the FOUPs of the sample D and the sample E, followed by sealing, the whole FOUPs were left to stand at room temperature for 60 minutes. After the ethanol solution of octadecylphosphonic acid was discharged, rinsing with ethanol was performed twice, and washing with water was further performed. They are a sample F and a sample G.

The water contact angles of the inner walls of these FOUPs were measured. The drop contact angle of the sample F was 103.8°, and the drop contact angle of the sample G was 107.7°. It is seen that surface hydrophobicity after the treatment increased in both of the samples. This is because the octadecylphosphonic acid undergoes a firm chemical bond to the outermost surface of the aluminum oxide. This is because phosphonic acid is chemically bonded even to the aluminum oxide with which the vicinity of the resin surface is impregnated, if its hydroxyl group bonded to aluminum is exposed to the surface.

Next, an HF exposure test was conducted on the FOUPs whose inner walls were treated. The same apparatus as that in Example 4 was used in the test. PCs having undergone the exposure test were partly cut out, and elemental compositions in their outermost surfaces were observed by XPS. The result showed that the content of F atoms in the surface of the sample D not having undergone the treatment was 25.5 atomic %, and the content of F atoms in the surface of the sample E was 48.3 atomic %. On the other hand, the content of F atoms in the surface of the sample F was 4.2 atomic %, and the content of F atoms in the sample G was 1.2 atomic %. It has been confirmed that the surfaces of the inner walls of the FOUPs were hydrophobized by the SAM and did not easily adsorb the HF elements having high polarity.

The hydrophobic layer formed on the aluminum oxide film using the phosphonic acid SAM is renewable by the following method. For an acceleration experiment, the surfaces where the hydrophobic layers are formed are irradiated with UV light, and the hydrophobic layers are once removed. In this state, the drop contact angle of the surface of the sample F was 89.2°, and the drop contact angle of the surface of the sample G was 88.8°. The inner walls of the samples were subjected to hydrophobization treatment by the same method as that in the first treatment. The drop contact angle of the sample F was 105.6°, and the drop contact angle of the sample G was 107.8°. It is seen that the hydrophobic layer can be thus renewable any number of times even if the hydrophobic layer deteriorates.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor wafer transport container comprising a resin container configured to store a semiconductor wafer,
wherein a vicinity of a surface of a resin of at least an inner surface of the resin container is impregnated with aluminum oxide having a hydroxyl group, and a structure in which 1 atomic % or more of the aluminum oxide in terms of concentration of elemental aluminum is dispersed in the resin is present within at least a range of not less than 50 nm nor more than 10 μm in depth from the inner surface.

2. The semiconductor wafer transport container according to claim 1, wherein a structure in which not less than 5 atomic % nor more than 30 atomic % of the aluminum oxide in terms of the concentration of elemental aluminum is dispersed in the resin is present within the range of not less than 50 nm nor more than 10 μm in depth from the inner surface.

3. The semiconductor wafer transport container according to claim 1, wherein a metal oxide film with a thickness of not less than 20 nm nor more than 1 μm is formed on the inner surface, of the resin container, impregnated with the aluminum oxide.

4. The semiconductor wafer transport container according to claim 3, wherein the metal oxide includes at least one selected from a group consisting of aluminum oxide, silicon oxide, and zirconium oxide.

5. The semiconductor wafer transport container according to claim 1, wherein a self-assembled monolayer containing an alkyl group with not less than 8 nor more than 32 carbon atoms is provided on the inner surface, of the resin container, impregnated with the aluminum oxide.

6. A semiconductor wafer transport container comprising a resin container configured to store a semiconductor wafer,
wherein a metal oxide film containing a metal oxide is formed on at least an inner surface of the resin container containing a resin, with a mixture layer of the resin and the metal oxide being present between the metal oxide film and the inner surface,
the metal oxide includes at least one selected from a group consisting of aluminum oxide, silicon oxide, and zirconium oxide.

7. The semiconductor wafer transport container according to claim 6, wherein the metal oxide film has a thickness of not less than 20 nm nor more than 1 μm, and the mixture layer has a thickness of not less than 10 nm nor more than 1 μm.

8. The semiconductor wafer transport container according to claim 6, wherein a self-assembled monolayer containing an alkyl group with not less than 8 nor more than 32 carbon atoms is provided on the inner surface, of the resin container, on which the metal oxide film is formed.

9. The semiconductor wafer transport container according to claim 8, wherein the metal oxide includes aluminum oxide, and the self-assembled monolayer has the alkyl group bonded to the aluminum oxide through a phosphonate ester.

10. The semiconductor wafer transport container according to claim 8, wherein the metal oxide includes silicon oxide, and the self-assembled monolayer has the alkyl group bonded to the silicon oxide through a siloxane bond.

11. A semiconductor wafer transport container comprising a resin container configured to store a semiconductor wafer,
wherein a self-assembled monolayer containing an alkyl group with not less than 8 nor more than 32 carbon atoms is provided on at least an inner surface of the resin container.

12. A method for manufacturing the semiconductor wafer transport container according to claim 1, the method comprising:
a step of exposing at least the inner surface of the resin container to alkylaluminum under a reduced pressure to impregnate an interior of the resin with the alkylaluminum; and
a step of exposing at least the inner surface of the resin container to an oxidizing agent selected from water, ozone, and plasma oxygen to oxidize the alkylaluminum with which an interior of the resin is impregnated.

13. The method for manufacturing the semiconductor wafer transport container, according to claim 12, wherein the step of the exposure to the alkylaluminum is executed under a reduced pressure where a partial pressure of the alkylaluminum is not less than 10 Pa nor more than 5 kPa, for duration of not shorter than 30 seconds nor longer than 1 hour.

14. The method for manufacturing the semiconductor wafer transport container, according to claim 12, further comprising a step of forming a metal oxide film on at least the inner surface, of the resin container, having undergone the step of the exposure to the alkylaluminum and the step of the exposure to the oxidizing agent.

15. The method for manufacturing the semiconductor wafer transport container, according to claim 12, further comprising a step of using at least one selected from alkylamine, alkylphosphonic acid, and alkylalkoxysilane, having an alkyl group with not less than 8 nor more than 32 carbon atoms to provide a self-assembled monolayer containing the alkyl group, on at least the inner surface, of the resin container, having undergone the step of the exposure to the alkylaluminum and the step of the exposure to the oxidizing agent.

16. A method for manufacturing the semiconductor wafer transport container according to claim 6, the method comprising:
a step of exposing at least the inner surface of the resin container to at least one selected from alkyl metal, alkoxy metal, and alkylamino metal under a pressure of not less than 1 Pa nor more than 300 Pa for duration of not shorter than 1 second nor longer than 10 seconds; and
a step of exposing at least the inner surface of the resin container to at least one oxidizing agent selected from water, ozone, and plasma oxygen,
wherein the step of the exposure to at least one selected from the alkyl metal, the alkoxy metal, and the alkylamino metal and the step of the exposure to the oxidizing agent are repeatedly executed not less than 10 times not more than 1000 times, to form the metal oxide film.

17. The method for manufacturing the semiconductor wafer transport container, according to claim 16, wherein the alkyl metal, the alkoxy metal, or the alkylamino metal contains, as the metal, at least one selected from a group consisting of aluminum, silicon, and zirconium.

18. The method for manufacturing the semiconductor wafer transport container, according to claim 16, further comprising a step of using at least one selected from alkylphosphonic acid and alkylalkoxysilane, having an alkyl group with not less than 8 nor more than 32 carbon atoms to provide a self-assembled monolayer containing the alkyl group, on the metal oxide film which is formed on at least the inner surface of the resin container through the repeated execution of the step of the exposure to the alkyl metal, the alkoxy metal, or the alkylamino metal and the step of the exposure to the oxidizing agent.

19. A method for manufacturing the semiconductor wafer transport container according to claim 11, the method comprising
a step of using at least one selected from alkylamine, alkylphosphonic acid, and alkylalkoxysilane, having an alkyl group with not less than 8 nor more than 32 carbon atoms to provide the self-assembled monolayer containing the alkyl group, on at least the inner surface of the resin container.
